(19) United States
(12) Patent Application Publication
(10) Pub. No.: US 2010/0289145 A1
(43) Pub. Date: Nov. 18, 2010

(54) WAFER CHIP SCALE PACKAGE WITH CENTER CONDUCTIVE MASS

(76) Inventors: Jayprakash Vijay Chipalkatti, Allen, TX (US); Matthew David Romig, Richardson, TX (US)

Correspondence Address: TEXAS INSTRUMENTS INCORPORATED, P O BOX 655474, M/S 3999, DALLAS, TX, 75265, US

(21) Appl. No.: 12/467,789

(22) Filed: May 18, 2009

(51) Int. Cl. H01L 23/522; H01L 21/768

(52) U.S. Cl. 257/758; 438/622; 257/E23.142; 257/E21.59

(57) ABSTRACT

A method and structure for an unencapsulated wafer section such as a wafer chip scale package (WCSP) includes a plurality of interconnect terminals and a pad metallization structure on an active surface of a WCSP chip. An area of the pad metallization structure is larger than an area of one of the interconnect terminals and, in an embodiment, larger than an area of two interconnect terminals. A plurality of conductive interconnects are attached to the plurality of interconnect terminals. The conductive interconnects are placed in contact with first lands of a supporting substrate, which can be a printed circuit board. Subsequently, a conductive mass is electrically coupled with a second land of the receiving substrate, with the second land being connected to at least one via of the supporting substrate which can, in turn, be connected to a plane of the supporting substrate. Improved thermal characteristics can result.

### FIELD OF THE INVENTION

The present invention relates generally to a system and method for integrated circuit packaging, and more particularly to a structure and method which enhances the performance of wafer chip scale packages.

### BACKGROUND OF THE INVENTION

Integrated circuit (IC) packaging plays a vital role in the continued development of integrated circuits. The IC device can include a semiconductor chip (chip, wafer section), and some form of packaging which protects the chip. Packaging can be a significant factor in the overall performance and desirability of the IC for a specific use. The size of the IC package which contains the chip, in part, dictates the final size of the electronic device containing the IC. Further miniaturizing semiconductor packages is a continuing goal of design engineers.

Various package designs have been developed in an attempt to minimize the size of the completed device. For example, one embodiment of a quad flat no-lead (QFN) device includes a semiconductor chip having an inactive (back) surface attached to a leadframe with chip attach material. An active (front, circuit) side of the chip faces away from the leadframe. Interconnect terminals (in this instance, bond pads) on the active surface of the chip are wire bonded to leads of the leadframe. The chip, chip pad, and a portion of the leads are encapsulated in plastic resin or other encapsulation material. To minimize device size of the QFN device, the leadframe leads exposed on the outer surface of the device are flush with surfaces of the encapsulated package. The leads can then be surface mounted to lands of a printed circuit board (PCB) or other substrate using solder or other conductive material.

The leadframe of a QFN device can also include an exposed thermal pad formed as a lower surface of the chip pad which is exposed by the encapsulation material. The exposed thermal pad can be attached to a ground land of a PCB or other substrate to function as a heat sink to draw heat away from the chip and package during operation.

Another type of package design which provides a small device footprint is wafer chip scale packaging (WCSP). WCSP offers a compact package for integrated circuits as a resin encapsulation is not required. With a WCSP device, solder balls (or similarly, solder bumps, posts, and so forth) can be directly attached to interconnect terminals of the semiconductor chip. Solder ball pitch can be as small as 500 micrometers or less. The active surface of the semiconductor chip is protected by a patterned passivation layer which can include, for example, various polymers, organic materials, etc., which protects the active surface of the semiconductor chip. The chip and solder balls are placed active-side down on a PCB or other substrate in a flip chip style attachment, and the solder balls are reflowed to electrically couple the bond pads on the chip with conductive lands on the PCB. Because they are not encapsulated, but instead use a thinner passivation layer for protection, WCSP devices also have the advantage of being thermally efficient. One (or more) solder ball can be connected to a PCB land, the land is connected with a trace, which is in turn connected to a via, and the via can be coupled with a plane, such as a ground plane, of the PCB. If more than one solder ball is coupled with the ground plane, these grounded solder balls can be designed and located at various sites around the active surface of the chip. Vias which are placed near or under a device are often referred to as “thermal vias,” even though their function is often for electrical as well as thermal conductivity. A “via” or “thermal via” generally refers to a conductor at least partially through a supporting substrate such as a PCB which can connect to at least one other conductive structure.

### SUMMARY OF THE EMBODIMENTS

In contemplating conventional semiconductor device packages, the inventors have realized that while devices formed as wafer chip scale packages (WCSP) are thermally efficient, they are not able to take advantage of a structure such as an exposed thermal pad as used with quad flat no-lead (QFN) devices. The exposed thermal pad of a QFN device is formed as a part of the leadframe chip pad, and thus a conventional exposed thermal pad formed from a leadframe cannot be provided with a WCSP device.

Even so, the inventors have realized that improved thermal efficiency may be desired with future WCSP devices. Consumer electronics and other device components and subsystems are continually being miniaturized and formed with ever-decreasing profiles. As such, the flow of heat away from operating devices becomes more difficult, and heat-related device problems may increase with future component designs, even with the use of thermally-efficient WCSP packages. Further, devices with higher power dissipation are not able to take advantage of WCSP packages because even WCSP thermal efficiency can be insufficient when used with these chip types. High power devices therefore typically include packaging in a QFN or quad flat package (QFP). These packages, however, have a larger footprint and thus do not achieve the degree of miniaturization that a WCSP package offers.

Packages such as ball grid array (BGA) devices can include the use of solder balls or bumps as thermal connections to ground planes of a supporting substrate such as a printed circuit board (PCB). With a BGA device, which includes an encapsulated chip, solder balls or bumps on the package contact thermal vias on the PCB to draw heat away from the functioning chip. BGA devices have larger package sizes compared with a WCSP device, and the heat can be more easily dissipated. In a conventional device, placing a WCSP solder ball over a thermal via on a PCB can deplete the solder of the solder ball as the solder flows into an opening in the center of the via, resulting in increased electrical resistance or an electrical open, and thus these types of thermal connections are not an option for WCSP devices which have a moderate or high power dissipation. To overcome solder depletion, filled vias on the PCB can be used, but this is an expensive technique and can increase the difficulty in manufacturing the PCB. Laser microvias can also be used to decrease solder depletion, but this is also an expensive process and is thus only used on high-end PCB's.

A conventional WCSP device may contain a plurality of interconnect terminals each connected to a ground plane, but these interconnect terminals can be located at various sites around the active surface of the chip. In contemplating a way to allow a WCSP package to connect to conventional thermal vias in a supporting substrate, the inventors have realized that a thermal connection having a mass larger than a mass of a solder ball can be formed between the active surface of the chip and the supporting substrate to which it is attached. The mass provided can be larger in the X/Y directions and maintain a thickness in the Z direction similar to a solder ball so that spacing between the WCSP device and a PCB to which it is attached is not altered. Grouping the grounded interconnect terminals together on the surface of the chip, for example at the center of the chip, would provide a way to form a large thermal connection. A pad metallization structure can be formed over an area of the chip, and one (or more) mass of thermally and/or electrically conductive material (a “conductive mass”) can be formed either on the pad metallization structure on the active surface of the chip or on a supporting substrate to contact the pad metallization structure on the active surface of the chip. The conductive mass can contact one (or more) thermal or ground land on the PCB, which in turn contacts one or more vias to a ground plane within the PCB, thus providing a structure which can be used to dissipate heat from an operating WCSP device. Further, because the volume of the conductive mass is larger than the volume of a solder ball or other conductive interconnect, solder depletion is reduced or eliminated.

Various embodiments of the invention as described below can provide a method and structure for one or more thermal vias from a WCSP package to a grounding structure of a supporting substrate such as a PCB.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1 is a perspective view of a conventional wafer scale chip package (WCSP);

FIG. 2 is a cross section of the FIG. 1 WCSP device and a printed circuit board which can receive the WCSP device;

FIG. 3 is a plan view of a WCSP device having a conductive mass according to an embodiment of the invention;

FIG. 4 is a cross section of the FIG. 3 WCSP device and a printed circuit board which can receive the WCSP device;

FIG. 5 is a plan view of another embodiment of the invention;

FIG. 6 is a magnified cross section of the FIG. 5 device;

FIG. 7 is a magnified cross section depicting an embodiment including conductive posts formed as conductive interconnects; and

FIG. 8 is a plan view depicting a printed circuit board including a pre-applied solder layer in preparation to receive an integrated circuit device.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to the present embodiments (exemplary embodiments) of the invention, an examples of which are illustrated in the accompanying drawings. Wherever possible, the same reference numbers will be used throughout the drawings to refer to the same or like parts.

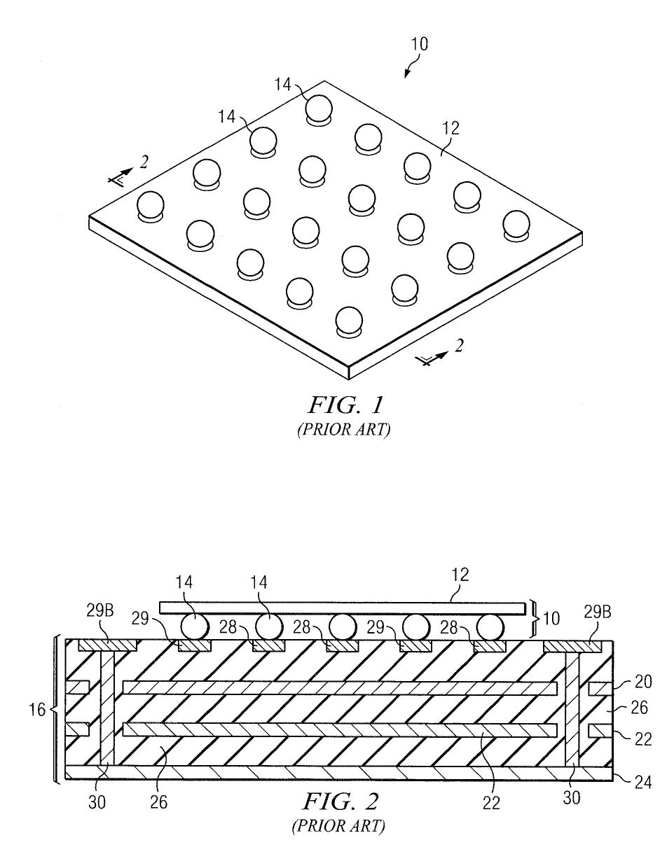

FIG. 1 is a perspective view depicting a conventional wafer chip scale package (WCSP) 10 including a semiconductor chip 12 having a plurality of solder balls 14, with each solder ball connected to an interconnect terminal (not individually depicted) on an active (front, circuit) side of the chip. The interconnect terminals and solder balls 14 are evenly spaced across the active surface of the chip arranged in a 4×5 grid.

FIG. 2 depicts a cross section of the FIG. 1 device along 2-2, and further depicts the structure after connection of the FIG. 1 device to a supporting substrate 16 such as a printed circuit board (PCB), ceramic substrate, etc. The PCB of FIG. 2 includes a plurality of conductive layers or traces 20-24 separated by at least one nonconductive (insulation) layer 26. Solder balls 14 are connected to interconnect lands 28, 29 on the PCB. The interconnect lands 28 can be can be connected to signal traces (not individually depicted). Interconnect lands 29 can be coupled to one or more traces (not individually depicted) which are connected to thermal lands 29B. Thermal lands 29B are also connected to thermal vias 30, which in turn connect with one or more ground planes 24 or a power supply. Thus circuitry on an active surface of the semiconductor chip 12 can be connected to the ground plane 24 of the PCB through an interconnect terminal (not depicted) on the chip 12, a solder ball 14 connected to the interconnect terminal, to a land 29 connected to a trace (not depicted), which connects with a thermal land 29 on the PCB, a PCB via 30 connected to the thermal land 29, and to the PCB ground plane 24.

To connect the solder balls 14 with interconnect lands 28, 29, the solder balls can be placed in physical contact with lands 28, 29, then the solder balls are reflowed, for example using the application of heat, to provide electrical, mechanical, and thermal coupling between the WCSP semiconductor device 10 and the PCB. In the conventional implementation of FIG. 2, thermal coupling between the device 10 and the thermal via 30 is less than desired, for example because the thermal vias 30 cannot be placed directly under the interconnect lands 29, but must be connected to lands 29 with a trace.

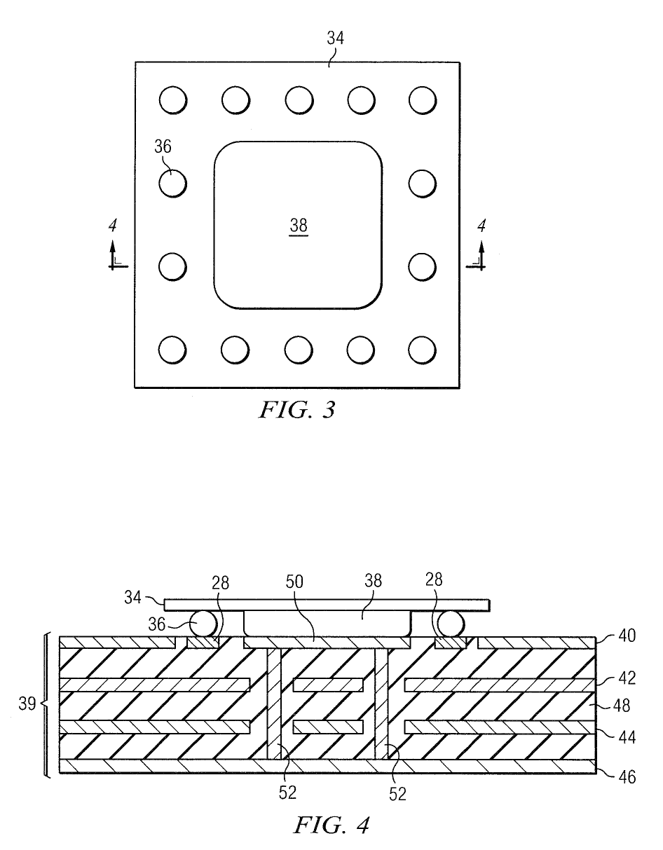

To accommodate the use of a conductive mass which, in an embodiment, can function as a heat sink for the chip, a WCSP structure similar to that depicted in the plan view of FIG. 3 can be formed. In this embodiment of the invention, a semiconductor wafer section such as a single unencapsulated semiconductor chip 34 or two or more unsingularized semiconductor dice includes a plurality of solder balls 36, and a passivation layer (not individually depicted) which protects at least an active surface of the chip. The passivation layer is patterned to expose interconnect terminals (not individually depicted) on the active surface of the chip 34. The FIG. 3 structure can further include a conductive mass 38, for example a solder layer having a volume of solder, which can connect to a pad metallization layer on the active surface of the chip. In this embodiment, the conductive mass 38 and pad metallization (not depicted) are centrally located on the active surface of the chip 34.

The solder balls can be in the range of from about 20 micrometers (μm) to about 500 μm in diameter, with a pitch of between about 50 μm and about 1,000 μm. Various metals and alloys would function sufficiently for the solder balls, such as a tin-lead alloy, a high-tin alloy, silver, and copper. In the FIG. 3 embodiment, the conductive mass 38 can be between about 300 μm and about 5,000 μm square and between about 5 μm and about 500 μm thick.

For simplicity of explanation, inventive embodiments are described with reference to the use of solder balls, but it is to be understood that conductive interconnects other than solder balls, such as bumps, posts, pillars, etc. manufactured from metals (gold, silver, copper, etc.), metal alloys (solder such as tin-lead solder, etc.), or other conductive materials (conductive paste such as silver-filled paste, etc.) are contemplated. In one alternative to solder balls, conductive posts such as copper posts can be formed, for example using a process similar to that described in U.S. Pat. No. 6,914,332, commonly assigned with the present application to Texas Instruments, Inc.

The pad metallization layer on the active surface of the chip which connects to the conductive mass 38 can be formed from an interconnect terminal metallization layer or another metallization layer such as a metal redistribution layer used for plural purposes, or from a separate metallization redistribution layer used specifically for connection with the conductive mass 38. To enhance thermal efficiency, the metallization layer can occupy as much of the active surface as possible, while avoiding electrical shorting or signal interference with the operating device.

In a device formed conventionally, six of 20 interconnect terminals might be connected with a ground plane. In the conventional device of FIG. 2, two of 20 solder balls are depicted as being connected to thermal lands 29 which are connected to vias 30, which are in turn connected to a ground plane 24. With the present embodiment, instead of using six grounded interconnect terminals at any location of the chip, a single pad metallization structure can be formed on the chip, for example at a central location. A volume of conductive material such as tin-lead solder or other alloys, silver, copper, nickel, palladium, gold, etc. is formed as a conductive mass 38 to contact the pad metallization structure on the active surface of the chip. Because the single conductive mass 38 replaces six individual solder balls connected with a ground plane, no chip functionality is lost. Further, the FIG. 3 structure can be designed to replace a conventional chip, as the remaining solder balls are located at conventional grid locations.

FIG. 4 is a cross section along 4-4 of the FIG. 3 WCSP structure, with the chip placed active-side down. The solder balls 36 and conductive mass 38 are depicted as being in physical contact with a supporting substrate 39 such as a PCB. In addition to the unencapsulated semiconductor chip 34, solder balls 36, and conductive mass 38 of the FIG. 3 device, FIG. 4 depicts a portion of a PCB including conductive layers or traces 40-46, one (or more) insulation layer 48, a conductive land 50 which is electrically connected with the conductive mass 38, and vias 52 which can connect with conductive trace 46 which, in this instance, can be a ground plane. The supporting substrate 39 can further include other traces, other insulation layers, or other features.

As depicted in the FIG. 4 embodiment, a height of a conductive mass 38 is about equal to a height of a solder ball 36. Because the heights are the same, both the solder balls and thermal pad will contact the conductive lands when placed on the PCB 39. When the conductive materials of the solder balls and conductive mass are flowed, electrical contact between the conductive mass and solder balls with the conductive lands 28, 50 is most likely to occur. FIG. 4 also depicts that the conductive mass is attached to the supporting substrate such that in a cross section perpendicular to the active surface of the semiconductor chip 12 and a major surface of the supporting substrate 12, the conductive mass 38 directly overlies the thermal via 52.

Subsequent to contacting the solder balls 36 and conductive mass 38 with conductive lands or traces on the PCB, the solder can be heated and flowed to provide an electrical and mechanical attachment between the WCSP device and the supporting substrate.

FIG. 3 depicts the solder balls 36 arranged in a grid similar to that depicted in FIG. 1 and with six interconnect terminals replaced with the conductive mass 38. This structure would function with designs in which six of 20 interconnect terminals, if formed conventionally, would be electrically coupled with a ground plane. With a conventional device, these six interconnect terminals can be placed at any location around the active surface of the chip on one of the grid locations. As previously discussed, the FIG. 3 embodiment locates these ground connections to the center of the chip and forms a single pad metallization on the chip. This pad metallization encompasses the central chip area which would contain six interconnect terminals.

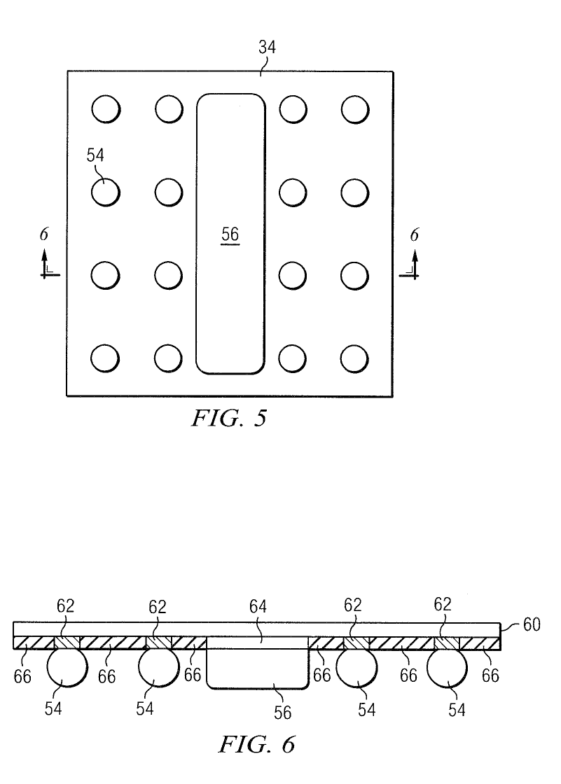

With some chip designs and uses, less than six of 20 conventional interconnect terminals may be connected with a ground plane. The device of FIG. 5 depicts a device which replaces four of 20 solder balls 54 with a conductive mass 56, for example because 16 of 20 interconnect terminals are required for input/output signals or other electrical connections to provide sufficient device operation. As will be understood by one of ordinary skill in the art, a pad metallization layer which replaces two or more interconnect terminals is contemplated.

FIG. 6 is a magnified cross section of the FIG. 5 structure. FIG. 6 depicts a semiconductor wafer section 60, for example formed from a portion of a silicon or gallium arsenide semiconductor wafer. FIG. 6 further depicts solder balls 54 electrically connected with interconnect terminals 62, and a conductive mass 56 formed, for example, from solder. The conductive mass 56 is connected with a pad metallization 64 formed on the active surface of the chip 60. The pad metallization layer 64 can be formed from the same layer as interconnect terminals 62, from another layer used for other purposes, or from a metallization layer which functions only as the pad metallization. FIG. 6 also depicts a passivation layer 66 which protects circuitry (not individually depicted) on the active side of the chip 60 and leaves exposed the interconnect terminals 62 and the pad metallization 64. Various other conductive mass and conductive ball, conductive bump, or conductive post arrangements will be realized by those of ordinary skill in the art from the present description. Conductive balls, bumps, or posts can be manufactured from metal such as solder or copper, or other conductive materials. Additionally, connections other than balls, bumps, or posts can also be used.

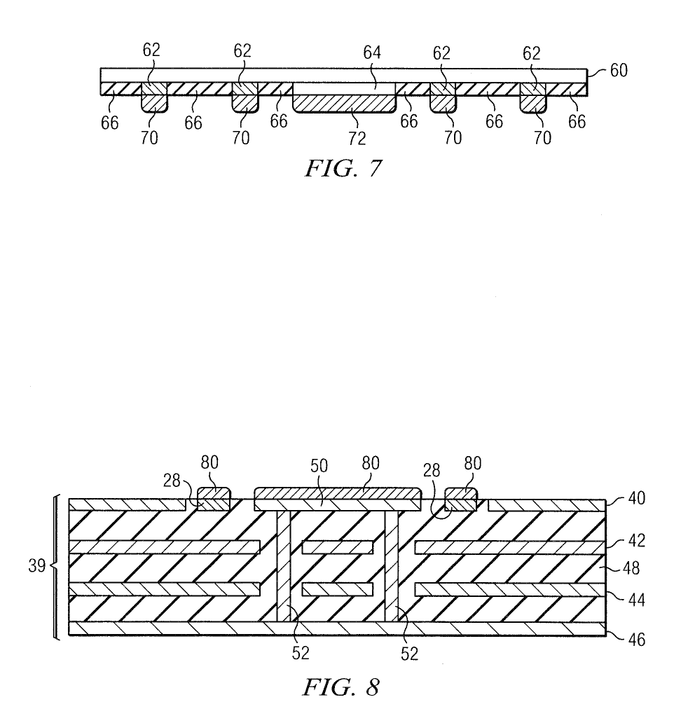

FIG. 7 depicts an embodiment including conductive posts 70 formed on interconnect terminals 62 over the active surface of the die 60. These posts can be formed from copper or another material according to U.S. Pat. No. 6,914,332, or a different process. The conductive mass 72 can be formed simultaneously with the posts 70 using the same process, formed at a different time using the same process, or formed using a different process, and can therefore include the same or a different material as posts 70. If manufactured from a material which is not designed to be reflowed, the conductive posts 70 and conductive mass 72 can be coupled to lands on a supporting substrate using, for example, solder.

Various other device arrangements which encompass an embodiment of the invention are contemplated. For example, more than one pad metallization 64 can be formed on the active surface of the chip 60, and more than one conductive mass 56 can be formed. The pad metallization and conductive mass can be formed at other locations on the chip, other than at the center as previously described.

Further, the conductive mass can be formed on a supporting structure land, similar to land 50 in FIG. 4, rather than being formed on the pad metallization 64. Forming the volume of the conductive mass on a land of the supporting substrate such as a PCB may have processing advantages over forming it directly on the pad metallization of the chip. Then, upon attachment of the chip to the supporting substrate, the pad metallization would contact the conductive mass. Upon flowing the conductive material of the solder balls, bumps, posts, etc., the material of the conductive mass could also be caused to flow and electrically couple with the pad metallization. If a material which is not designed to be reflowed is used for the conductive interconnects and/or conductive mass, they can be electrically and/or thermally coupled using a material such as solder or conductive paste.

Additionally, the solder balls, bumps, posts, etc., can be formed from a first material, while the conductive mass is formed from a second, different material. The two materials can have, for example, different flow temperatures or other manufacturing or operating characteristics. In one embodiment, the balls, bumps, posts, etc. can be formed from solder while the conductive mass is formed from a material having a higher melting temperature than solder such as copper.

To form a copper pad metallization on the chip, a process similar to that described in U.S. Pat. No. 6,914,332, referenced above, can be used. In this use, a solder conductive mass (or thinner solder layer, whichever is needed based on the thickness of the copper pad metallization) can be formed on the supporting substrate such as a PCB rather than on the pad metallization of previous embodiments. As with previous embodiments, the solder balls can be formed on the interconnect terminals of the chip. The solder balls can be placed in contact with lands of the PCB, which results in contact between the copper conductive mass on the metallization pad and the solder on the PCB land. Next, the solder can be flowed to physically and electrically couple the WCSP device with the PCB.

In another embodiment, a conductive interconnect can be formed on the interconnect terminals of the chip, and a copper conductive mass can be formed on the pad metallization of the chip. These structures can also be formed using a process similar to that described in U.S. Pat. No. 6,914,332, which has been referenced above. In this embodiment, the copper bumps, pillars, or posts are formed on the interconnect terminals, and a copper conductive mass can be formed on the pad metallization of the chip. A conductive material such as solder, a conductive paste, or other conductive material can be used to physically and electrically couple the copper structures to lands of a supporting substrate such as a PCB. This can be performed using known techniques for applying a conductive material such as solder to the PCB in advance of receiving the chip. For example, FIG. 8 depicts a PCB having solder, conductive paste, or another conductive material 80 pre-applied to the conductive land 50 and interconnect land 28, for example using a process such as screen printing in advance of integrated circuit attachment. The conductive material is applied to a uniform thickness in preparation of receiving the device, for example the device of FIG. 7. During attachment, the contacts 70, 72 of the WCSP device are placed in contact with the conductive material 80 on the PCB, then the conductive material is reflowed to electrically, mechanically, and thermally attach the WCSP device to the PCB.

To determine the effectiveness of a conductive mass formed in accordance with an embodiment of the invention, a series of thermal simulations was performed. In one of these simulations, a WCSP device including the conductive mass in accordance with one embodiment had a temperature decrease of more than 19% over a similar device formed according to a conventional design. Further, the inventive device has a smaller footprint than a device such as a QFN package and thus is more desirable with regard to space considerations.

For purposes of the present invention, “encapsulation” is contrasted with “passivation” in that passivation can include openings to expose interconnect terminals on the wafer section. A passivation layer is also formed to be a thinner layer an encapsulation. For example, while a passivation layer can be in the range of between about 0.1 μm to about 15 μm, a thickness of an encapsulation layer is typically at least 300 μm thick. Because of its minimum thickness, a passivation layer has little or no effect on the thermal properties of the package. In contrast, an encapsulation layer restricts heat flow away from the encapsulated die and therefore has a negative effect on the thermal property of the package. A passivation layer is typically applied to the entire wafer and cured before any die singulation, for example using a wafer saw, while encapsulation is conventionally applied to each individual die and cured after singulation and some level of assembly processing such as wire bonding or flip chip interconnection. Further, a passivation layer is often used in conjunction with redistribution layers.

The volume of the conductive mass applied to the pad metallization relative to the volume of solder of a solder ball, bump, post, etc., depends on the number of solder balls the conductive mass is replacing, the pitch of the solder balls it is replacing, and the size of the solder balls it is replacing. In the FIG. 3 embodiment, the conductive mass 38 is replacing six solder balls. The conductive mass will have an area which is more than six times the area of an individual interconnect terminal. The conductive mass applied to the pad metallization, in an embodiment, can be formed over the entire area within a perimeter which would be occupied by six interconnect terminals which would have solder balls. Thus the volume of the conductive mass applied to the pad metallization will likely be much more than six times the volume of six solder balls it is replacing. In many embodiments, the X/Y area of the conductive mass will be at least twice the X/Y area of an individual interconnect terminal it is replacing, and the volume of the conductive mass will be at least twice the volume of a solder ball, bump, or post it is replacing.

An embodiment of the inventive device can be used, for example, when it is desirable to place a conductive interconnect of small dimensions on a thermal via of a supporting substrate such as a PCB. A thermal via can be formed by mechanical drilling and metal plating. In conventional structures, the pitch and volume of these small conductive interconnects is not conducive to placement on a thermal via. For example, the volume of the small conductive interconnect can be depleted by the thermal via, thereby resulting in an increased electrical resistance or an electrical open of the conductive interconnect. By grouping plural conductive interconnects into one (or more) large conductive mass, the volume of material is increased, volume depletion is reduced, and no device functionality has been compromised.

An embodiment of the inventive device can also be used, for example (with reference to FIG. 2), when it is desirable that a pitch of the conductive interconnects 14 is equal to or less than the sum of the diameter of the interconnect land 28 and the thermal land 29 on the supporting substrate 16 such as a PCB. For example, a PCB formed with current technology can have an interconnect land diameter between 200 μm and 400 μm, and a thermal land diameter between 300 μm and 500 μm. An embodiment could be used for a device with a pitch that is less than about 900 μm. It is expected that the typical size of interconnect landing pads and thermal via pads will reduce over time through miniaturization and advanced technology such as laser vias. It is reasonably expected that as these reduce, an embodiment could be used for any devices with an interconnect pitch that is equal to or less than the sum of the diameter of the interconnect landing pad 28 and the thermal via pad.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A semiconductor device comprising:
a semiconductor chip;
a plurality of interconnect terminals on an active surface of the semiconductor chip, wherein each interconnect terminal has an area;
at least one pad metallization structure on the active surface of the semiconductor chip, wherein the pad metallization structure has an area greater than an area of each interconnect terminal;
a plurality of conductive interconnects, with each conductive interconnect electrically coupled with one of the interconnect terminals; and
at least one conductive mass coupled with the at least one pad metallization structure, wherein an area of the conductive mass is larger than an area of one of the interconnect terminals and a volume of the conductive mass is larger than a volume of one of the conductive interconnects.

2. The semiconductor device of claim 1, further comprising:
a supporting substrate having a plurality of first lands and at least one second land which is larger than each first land;
at least one via electrically coupled with the second land and with a plane of the supporting substrate;
each of the plurality of conductive interconnects electrically coupled with one of the plurality of first lands; and
the at least one conductive mass electrically coupled with the at least one second land.

3. The method of claim 2 wherein, in a cross section perpendicular to an active surface of the semiconductor chip and a major surface of the supporting substrate, the conductive mass directly overlies the via.

4. The semiconductor device of claim 2 further comprising a passivation layer over the active surface of the semiconductor chip which exposes the plurality interconnect terminals and the at least one pad metallization structure.

5. The semiconductor device of claim 1, wherein the area of the pad metallization structure is at least two times the area of each interconnect terminal.

6. The semiconductor device of claim 1, wherein the volume of the conductive mass is at least two times the volume of one of the conductive interconnects.

7. The semiconductor device of claim 1 wherein the conductive interconnects comprise at least one material selected from the group consisting of tin, lead, silver, and copper.

8. The semiconductor device of claim 7 wherein the conductive mass comprises at least one material selected from the group consisting of tin, lead, silver, and copper.

9. The semiconductor device of claim 1 wherein the conductive mass comprises at least one material selected from the group consisting of copper, nickel, palladium, and gold.

10. The semiconductor device of claim 1 wherein the conductive interconnects and the conductive mass comprise at least one material selected from the group consisting of copper, nickel, palladium, and gold.

11. The semiconductor device of claim 1 wherein the interconnect terminals and the pad metallization structure are formed from the same layer.

12. A method for forming a semiconductor device, comprising:
providing a semiconductor chip comprising:
a plurality of interconnect terminals over an unencapsulated semiconductor chip;
at least one pad metallization structure over the unencapsulated semiconductor chip, wherein an area of the at least one pad metallization structure is larger than an area of two of the interconnect terminals; and
a plurality of conductive interconnects, wherein one conductive interconnect is located on each of the interconnect terminals;
placing the plurality of conductive interconnects in contact with a plurality of conductive first lands on a supporting substrate;
interposing at least one conductive mass between the at least one pad metallization structure and at least one second land on the supporting substrate, wherein an area of the at least one second land is larger than an area of at least two of the interconnect terminals; and
electrically coupling the at least one second land with at least one via which extends at least partially through the supporting substrate.

13. The method of claim 12 further comprising forming the at least one conductive mass on the at least one pad metallization structure, wherein a volume of the at least one conductive mass is larger than a volume of two of the conductive interconnects.

14. The method of claim 13 further comprising forming both the plurality of conductive interconnects and the at least one conductive mass from at least one material selected from the group consisting of tin, lead, silver, and copper.

15. The method of claim 13 further comprising forming both the plurality of conductive interconnects and the at least one conductive mass from at least one material selected from the group consisting of copper, nickel, palladium and gold.

16. The method of claim 13 further comprising:
forming the plurality of conductive interconnects from at least one material selected from the group consisting of tin, lead, silver, and copper; and
forming the conductive mass from at least one material selected from the group consisting of copper, nickel, palladium, and gold.

17. The method of claim 12 further comprising forming the at least one conductive mass on the at least one second land, wherein a volume of the at least one conductive mass is larger than a volume of two of the conductive interconnects.

18. The method of claim 17 further comprising forming both the plurality of conductive interconnects and the at least one conductive mass from at least one material selected from the group consisting of tin, lead, silver, and copper.

19. The method of claim 17 further comprising forming both the plurality of conductive interconnects and the at least one conductive mass from at least one material selected from the group consisting of copper nickel, palladium and gold.

20. The method of claim 17 further comprising:
forming the plurality of conductive interconnects from at least one material selected from the group consisting of tin, lead, silver, and copper; and
forming the conductive mass from at least one material selected from the group consisting of copper, nickel, palladium, and gold.

21. The method of claim 13 further comprising electrically coupling the via with a plane of the supporting substrate.

22. The method of claim 21 further comprising electrically coupling the plane of the supporting substrate with one of ground and a power supply.

23. The method of claim 12 further comprising attaching the conductive mass to the supporting substrate such that in a cross section perpendicular to an active surface of the semiconductor chip and a major surface of the supporting substrate, the conductive mass directly overlies the via.

24. The method of claim 13 further comprising forming at least one redistribution layer during the formation of the at least one pad metallization structure over the unencapsulated semiconductor chip.

25. The method of claim 12 further comprising forming the via using mechanical drilling and metal plating.
